(19) United States
(12) Patent Application Publication
(10) Pub. No.: US 2021/0210269 A1
(43) Pub. Date: Jul. 8, 2021

(54) SOLAR CELL DEGAUSSING DEVICE, SOLAR CELL PRODUCTION SYSTEM AND SOLAR CELL DEGAUSSING METHOD

(71) Applicant: MiaSole Equipment Integration (Fujian) Co., Ltd., Duanzhou, Fujian (CN)

(72) Inventors: Wenbiao Yao, Quanzhou, Fujian (CN); Bo Zhou, Quanzhou, Fujian (CN); Qizheng Jiang, Quanzhou, Fujian (CN); Jianghui Huang, Quanzhou, Fujian (CN); Bin Zhang, Quanzhou, Fujian (CN); Jun Tan, Quanzhou, Fujian (CN)

(21) Appl. No.: 16/075,579

(22) PCT Filed: Jul. 10, 2018
(86) PCT No.: PCT/CN2018/095156

§ 371 Date: Aug. 3, 2018

(30) Foreign Application Priority Data
Nov. 1, 2017 (CN) 201721440348.8

(51) Int. Cl. H01F 13/00; H01L 31/18

(52) U.S. Cl. CPC H01F 13/006; H01L 31/0322; H01L 31/18

(57) ABSTRACT

The present disclosure provides a solar cell degaussing device, a solar cell production system and a solar cell degaussing method, the solar cell degaussing device comprises: a controller, a degausser, a sensing unit and a switching unit; the controller is connected to the sensing unit and the switching unit respectively; the switching unit is connected to the degausser; after the sensing unit detects presence of a cell slice, the controller triggers the switching unit to act so as to enable the degausser to be powered, and the powered degausser performs a degaussing treatment to the cell slice. The present disclosure solves the problem of lack of a cell slice degaussing device in the field of solar cell production, and the present device thereby can eliminate the magnetic of a magnetized cell slice, decrease the magnetic adsorption phenomena of facilities, and thus improve production efficiency.

### CROSS-REFERENCE TO RELATED APPLICATION(S)

This application is a 371 U.S. National Phase of International application No. PCT/CN2018/095156, filed Jul. 10, 2018, and claims benefit/priority of Chinese patent application No. 201721440348.8, filed Nov. 1, 2017 entitled “Solar Cell Degaussing Device”, the contents of all of which are incorporated herein by reference in entirety.

### TECHNICAL FIELD

The present disclosure relates to the field of thin film solar cells, particularly to a solar cell degaussing device, a solar cell production system and a solar cell degaussing method.

### BACKGROUND ART

For products of thin film solar cell with iron as a main ingredient of a substrate material, for example, flexible copper indium gallium selenide solar thin films, a magnet is mostly used in a production process thereof for position control, and in this process, a cell slice will be magnetized, occurrence of magnetic adhesion may be thus caused, and an automatic production line for producing cell slices is usually affected by magnetic absorption, specifically, a relatively long cell slice is cut by a cutter into relatively short cell slices, which are conveyed by a conveying belt to a sorting machine, in this process, since the cutter is made of a steel and iron alloy material, and a cutter bracket is also made of iron, a magnetized cell slice is likely to be adsorbed onto the cutter, and cannot be transferred to the sorting machine of next phase, which affects the manufacturing efficiency.

### SUMMARY

Objects of the present disclosure include, for example, providing a solar cell degaussing device, so as to realize on-line degaussing for a cell slice with a metal substrate.

Objects of the present disclosure further include providing a solar cell production system for solar cells, which includes the above solar cell degaussing device, and has all features of this solar cell degaussing device.

Objects of the present disclosure further include providing a solar cell degaussing method, which can realize on-line degaussing for a cell slice with a metal substrate through this method using the above solar cell degaussing device.

A technical solution used in an embodiment of the present disclosure is as follows:

A solar cell degaussing device includes: a controller, a degausser, a sensing unit and a switching unit; the controller is connected to the sensing unit and the switching unit respectively; the switching unit is connected to the degausser; after the sensing unit detects presence of a cell slice, the controller triggers the switching unit to act so as to enable the degausser to operate, for performing a degaussing treatment to the cell slice.

Optionally, the solar cell degaussing device further includes: a transfer unit configured to carry the cell slice; the degausser is mounted on the transfer unit.

Optionally, the transfer unit includes a plurality of rollers configured to bear the cell slice; the degausser on the transfer unit is configured for the cell slice to pass through.

Optionally, the degausser is in a frame-type structure.

Optionally, the solar cell degaussing device further includes: a residual magnetism meter; the residual magnetism meter is mounted behind the degausser according to an operation direction of the transfer unit.

Optionally, the residual magnetism meter is configured to monitor a residual magnetization intensity of the cell slice after being degaussed.

Optionally, the residual magnetism meter is connected to the controller; the controller adjusts an operation power of the degausser or controls a driving speed of the transfer unit according to the residual magnetization intensity.

Optionally, the sensing unit is mounted in front of the degausser.

Optionally, a further sensing unit, configured to control the degausser in a delayed manner, is provided behind the degausser.

Optionally, the solar cell degaussing device further includes: a first power supply and a second power supply; the first power supply is connected to the controller and the sensing unit respectively; the switching unit is connected to the second power supply and the degausser respectively.

Optionally, the first power supply is a direct current power supply, and the second power supply is an alternating current power supply.

Optionally, an output voltage of the direct current power supply is 24V, and an output voltage of the alternating current power supply is 220V.

Optionally, the sensing unit is a chromatic aberration sensor.

Optionally, the switching unit is a relay.

Optionally, the relay is a time-delay relay.

An embodiment of the present disclosure provides a solar cell production system configured to produce solar cells, including the solar cell degaussing device mentioned above.

An embodiment of the present disclosure provides a solar cell degaussing method, using the above solar cell degaussing device, and the method includes: powering on the solar cell degaussing device, after the sensing unit detecting the cell slice, the controller triggering the switching unit to act so as to enable the degausser to operate, for performing a degaussing treatment to the cell slice.

Optionally, the method further includes: a residual magnetization intensity of the cell slice after being degaussed has been tracked and detected, and afterward the controller adjusting an operation power of the degausser or controlling a driving speed of the transfer unit for the transmission of the cell slice according to the residual magnetization intensity.

Optionally, the method further includes: after a further sensor provided behind the degausser according to a cell slice forwarding direction detects no cell slice, the controller controlling the switching unit to enable the degausser to end the degaussing.

Compared with the prior art, beneficial effects of the embodiments of the present disclosure at least include: For the field of solar cell production at present, the present disclosure designs the degaussing device for the solar cell with a metal substrate, and the solar cell degaussing device of the present disclosure can eliminate the magnetic of the magnetized cell slice, decrease the magnetic adsorption phenomena of facilities, and thus improve production efficiency; moreover, furthermore, in preferred solutions of the present disclosure, measurement of the residual magnetism is also taken into consideration, such that a residual magnetism quantity is visible and controllable.

### BRIEF DESCRIPTION OF DRAWINGS

In order to make the objects, technical solutions and advantages of the present disclosure more clearer, the present disclosure will be further described below in combination with figures, wherein

FIG. 1 is a schematic diagram of an embodiment of a solar cell degaussing device provided in the present disclosure;

FIG. 2 is a schematic diagram of an embodiment of a solar cell degaussing device provided in the present disclosure;

FIG. 3 is a schematic diagram of an embodiment of a solar cell degaussing device provided in the present disclosure, showing a residual magnetism meter being connected to a controller;

FIG. 4 and FIG. 5 are schematic diagrams of a further embodiment of a solar cell degaussing device provided in the present disclosure; and

FIGS. 6-9 are flow charts of a solar cell degaussing method provided in the present disclosure.

### REFERENCE SIGNS

1 cell slice;

2 transfer unit;

3 degausser;

4 residual magnetism meter;

5 chromatic aberration sensor;

6 cell slice roll;

7 baffle;

8 bracket;

9 rotation shaft.

### DETAILED DESCRIPTION OF EMBODIMENTS

In order to make the objects, technical solutions, and advantages of the embodiments of the present disclosure clearer, below the technical solutions in the embodiments of the present disclosure will be described clearly and completely in conjunction with the figures in the embodiments of the present disclosure, apparently, some but not all embodiments of the present disclosure are described. Generally, components in the embodiments of the present disclosure described and shown in the figures herein can be arranged and designed in different configurations.

Therefore, the detailed description below of the embodiments of the present disclosure provided in the figures is not intended to limit the scope of protection of the present disclosure, but merely represents chosen embodiments of the present disclosure. Based on the embodiments of the present disclosure, all other embodiments obtained by a person ordinarily skilled in the art without paying inventive efforts shall fall within the scope of protection of the present disclosure.

It should be noted that similar reference signs and letters represent similar items in the following figures, therefore, once a certain item is defined in one figure, it is not needed to be further defined or explained in subsequent figures.

In the description of the present disclosure, it should be indicated that orientational or positional relationships indicated by terms such as “center”, “upper”, “lower”, “left”, “right”, “vertical”, “horizontal”, “inner”, and “outer” are based on orientational or positional relationships as shown in the figures, or orientational or positional relationships of a product of the present disclosure when being conventionally placed in use, merely for facilitating describing the present disclosure and simplifying the description, rather than indicating or suggesting that related devices or elements have to be in the specific orientation or configured and operated in a specific orientation, therefore, they should not be construed as limiting the present disclosure.

Besides, terms such as “first”, “second”, and “third” are merely for distinctive description, but should not be construed as indicating or implying relative importance.

Moreover, terms such as “horizontal” and “vertical” do not mean that a component is required to be absolutely horizontal or suspending, but can be slightly inclined. For example, by “horizontal” it merely means that a structure is more horizontal in comparison with “vertical”, rather than being completely horizontal, while the structure can be slightly inclined.

In the description of the present disclosure, it also should be indicated that unless otherwise specified and defined clearly, terms “provide”, “mount”, “join”, and “connect” should be understood in a broad sense, for example, a connection can be a fixed connection, a detachable connection, or an integrated connection; it can be a mechanical connection or an electrical connection; it can be a direct connection or an indirect connection through an intermediate medium, and it also can be an inner communication between two elements. For a person ordinarily skilled in the art, specific meanings of the above-mentioned terms in the present disclosure can be understood according to specific circumstances.

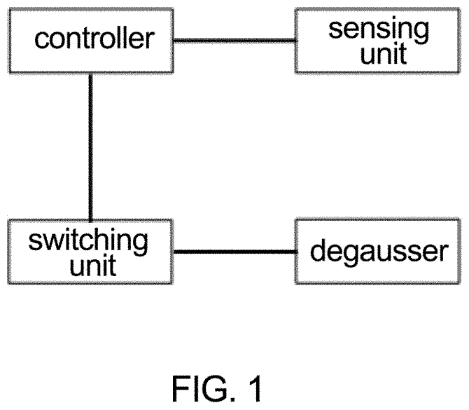

The present disclosure provides an embodiment of a solar cell degaussing device, as shown by a block diagram of FIG. 1, which mainly includes: a controller, a degausser, a sensing unit and a switching unit, for a specific electrical connection manner, reference can be made to FIG. 1, in which the controller is connected to the sensing unit and the switching unit respectively, and the switching unit is further connected to the degausser; in the present embodiment, a manner of operation of a solar cell degaussing device according to the present disclosure is as follows:

After the device is powered on, the sensing unit outputs a high (or low) level to the controller after detecting presence of a cell slice, after receiving this high (or low) level, the controller triggers the switching unit to act so as to enable the degausser to be powered, and the powered degausser starts to operate to perform a degaussing treatment to the cell slice; it should be indicated that the cell slice referred to herein also can be called as a cell strip; it should be explained herein that an existing power supply of a solar energy production line, for example, a power supply unit of a conveying control system, can be used to power on the preceding device, power-on refers to supplying power to the degausser through the switching unit by the controller and the sensing unit, of course, taking lean control and mutual interference between systems into consideration, independent power supplies also can be provided for the present embodiment, and the independent power supplies will be described below.

The above embodiment further includes a transfer unit configured to carry the cell slice, the degausser mentioned in the preceding is mounted on this transfer unit, that is, the cell slice is placed on a transfer unit driven by a motor, for example, a transmission roller and a conveying belt, and is subjected to the degaussing treatment when the cell slice pass through the degausser that operates after being powered, avoiding tedious procedures from carrying the cell slice by manual or other mechanisms.

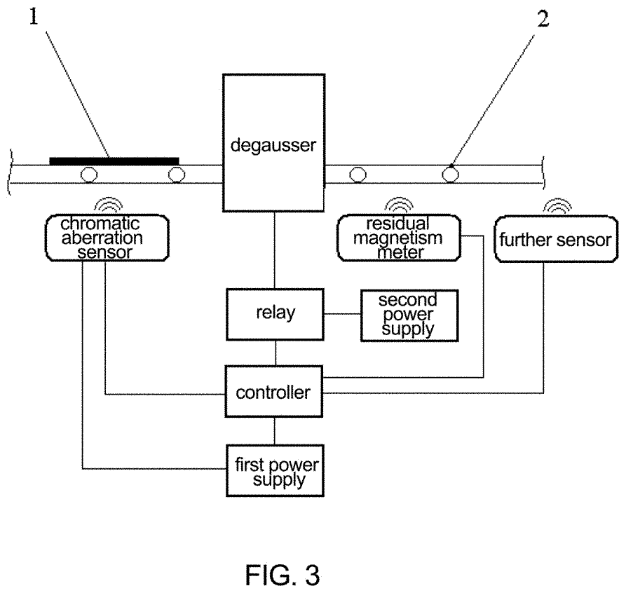

Furthermore, on the basis of the above embodiment, the present disclosure proposes to mount a residual magnetism meter behind the degausser, which residual magnetism meter is configured to track and monitor a residual magnetization intensity of the cell slice after being degaussed, wherein two points should be explained: firstly, “behind” herein refers to an output direction of the cell slice after passing through the degausser, and in combination with the transfer unit mentioned in the preceding, the residual magnetism meter is mounted behind an output end of the degausser according to a forward operation direction of the transfer unit; secondly, this residual magnetism meter can be device with a visualization screen such as a digital display, and it also can be connected to the controller (as shown in FIG. 3), and visualizationable information is collected and output by the controller, thereby the overall degaussing process is controllable, for example, an operation power of the degausser can be adjusted or a driving speed of the transfer unit can be controlled according to a value of residual magnetism.

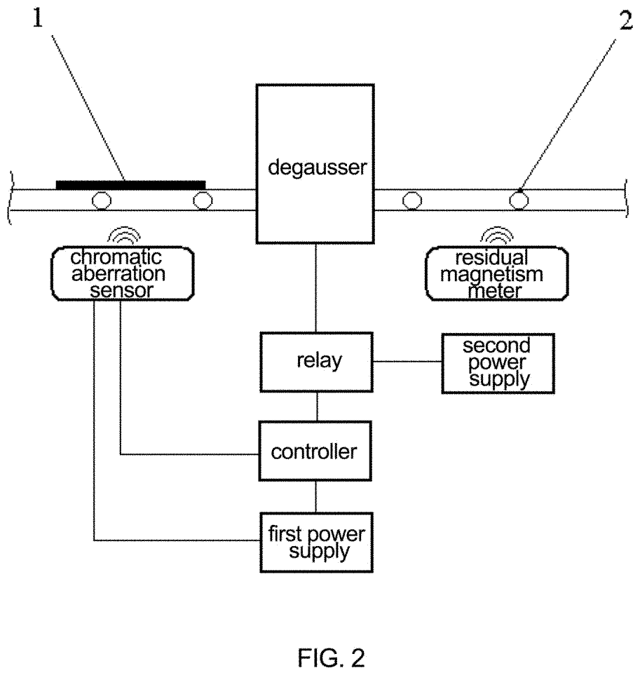

Summing up the above embodiments and preferred solutions, the present disclosure provides a specific embodiment, as shown by the schematic diagram of FIG. 2, in this embodiment, the present degaussing device can include a transfer unit 2 and a residual magnetism meter, and further includes a first power supply and a second power supply serving the present embodiment independently, the first power supply is connected to a controller and a sensing unit respectively, and configured to supply power to the controller and the sensing unit, a switching unit is connected to the second power supply and the degausser respectively, that is, the second power supply supplies power to the degausser through the switching unit; in the present embodiment, the sensing unit can be any detecting means such as chromatic aberration sensor, camera, and optical grating module configured to judge whether there is a cell slice on the transfer unit or not, moreover, in the present embodiment, the sensing unit is provided in front of the degausser, that is, as mentioned in the preceding, the sensing unit is provided before an input end of the degausser according to a forwarding direction F of the cell slice; in the present embodiment, the switching unit can be a relay that is easy in implementation and low in cost, and of course, it also can be a contactor, a silicon-controlled rectifier, a thyristor circuit, etc..

Taking the above specific parts as an example, an operating principle of the present embodiment can be as follows:

The first power supply and the second power supply are turned on, the controller and the chromatic aberration sensor are powered on, and one normally open contact end of the relay is powered;

When the transfer unit 2 (which can be a transmission roller without a belt, merely schematically shown in FIG. 2) conveys the cell slice 1 on the production line to a position of the chromatic aberration sensor, the chromatic aberration sensor detects the presence of the cell slice 1, and then outputs a high level to the controller;

The controller, after receiving this high level, outputs a control signal to a coil of the relay, the coil after being powered triggers the above mentioned normally open contact to close, then an electrical power of the second power supply is transmitted from the relay to the degausser;

The degausser starts to operate after being powered, the cell slice 1 is conveyed by the transfer unit 2 to slowly pass through the degausser, and the powered degausser generates an alternating magnetic field, so as to perform a uniform degaussing treatment to the forwarding cell slice 1;

The degaussed cell slice 1 passes by the residual magnetism meter behind the degausser, which residual magnetism meter outputs a residual magnetism numerical value of the cell slice in a digital display manner;

In front of the degausser, as the cell slice 1 forwarding, the chromatic aberration sensor outputs a low level to the controller when detecting no cell slice, and after receiving the low level, the controller cuts off the output to the relay, thus the power supplied by the second power supply to the degausser is cut off, and the degaussing is ended. It should be supplemented herein that taking an operating speed of the transfer unit 2 and an interval between the sensing unit and the degausser into consideration, in another preferred embodiment of the present disclosure, a time-delay relay is used as the switching unit, thus when the cell slice 1 leaves a detecting area of the chromatic aberration sensor, the time-delay relay does not immediately cut off the power supplied to the degausser, but after a pre-set period of time lapses, for example, after 10 minutes, a contact of the time-delay relay is restored, thereby ensuring that the cell slice 1 can be completely degaussed by the degausser, and occurrence of a small part of the cell slice 1 which is not degaussed is avoided.

In another embodiment of the present disclosure, in order to ensure complete degaussing of the cell slice, it is considered that a further sensing unit also can be provided behind the degausser and configured to control the degausser in a delayed manner according to a state of presence or absence of the cell slice (as shown in FIG. 3), thus the power consumption can be reasonably managed and controlled more precisely.

Finally, it should be indicated that, firstly, according to models of various parts, power supplies of different specifications can be used as the first power supply and the second power supply mentioned in the preceding, for example, in the above embodiment, the first power supply can be a direct current power supply, for example, a 24V power supply commonly used in industry control, and the second power supply can be an alternating current power supply outputting 220V; secondly, in practical operations, the degausser mentioned in the preceding can be in a frame-type structure, such that all of upper and lower faces and a periphery of the cell slice can be completely degaussed; thirdly, the above embodiments and preferred solutions thereof can be adjusted according to requirements of dimension, such that they can perform the degaussing treatment for other facilities or products on the solar energy production line, for example, cutter device mentioned in the preceding text.

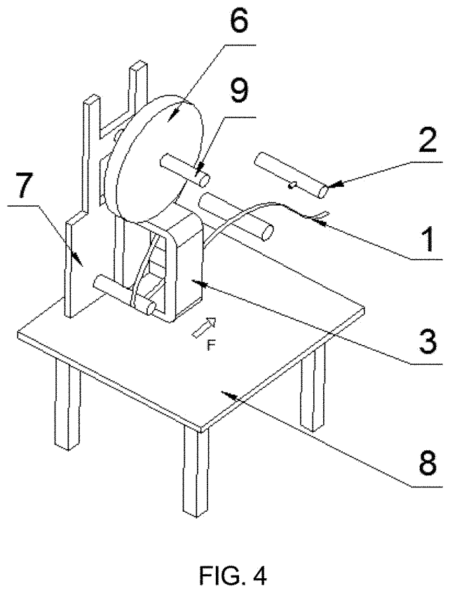

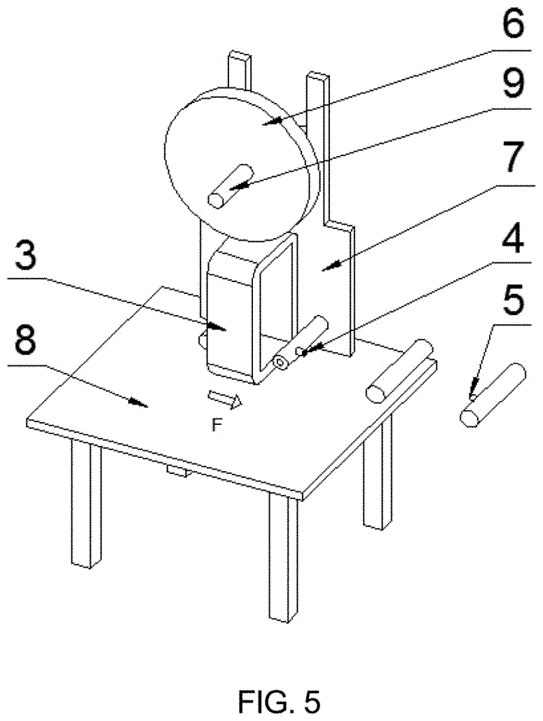

The present disclosure provides another embodiment of the solar cell degaussing device, as shown in FIG. 4 and FIG. 5, and the solar cell degaussing device of the present embodiment can be configured as an independent device for degaussing the cell slice, and also can be assembled in a solar cell production system to degauss cell slices in the production system. A controller, a degausser, a sensing unit, a transfer unit, a switching unit, a first power supply and a second power supply of the device of the present embodiment are functionally identical with those of the above embodiment, and they will not be repeatedly described. In the device of the present embodiment, a baffle 7 is mounted on a bracket 8, and a rotation shaft 9 is provided in an upper portion of the bracket 7. The cell slice 1 is rolled on a cell slice roll 6, and the cell slice roll 6 is fit on the rotation shaft 9. In an operation process of the solar cell degaussing device, the cell slice roll 6 can rotate on the rotation shaft 9, meanwhile, the cell slice 1 is released from the cell slice roll 6. As shown in FIG. 4, the degausser 3 is arranged below the cell slice roll 6, and the cell slice 1 is born on the transfer unit, for example, a roller 2.

It should be indicated that as in the above embodiment, the sensing unit such as a chromatic aberration sensor (not shown in FIG. 5) is provided in front of the degausser 3 according to a forwarding direction of the cell slice 1, and although not shown in the figures, this chromatic aberration sensor can be provided at any position suitable for detecting whether there is the cell slice 1, for example, this chromatic aberration sensor can be provided on the rotation shaft 9, or provided in a position of the degausser 3 close to the cell slice roll 6. Besides, the device of the present embodiment is provided with a residual magnetism meter 4 on one roller 2, and provided another roller 2 with another sensing unit, for example, a chromatic aberration sensor 5, which is configured to control the degausser 3 in a delayed manner, as shown in FIG. 5.

An operating principle of the solar cell degaussing device of the present embodiment can be as follows:

The first power supply and the second power supply are turned on, the controller and the chromatic aberration sensor (not shown in FIG. 4 or FIG. 5) are powered on, and one normally open contact end of the switching unit, for example, the relay, is powered; when the transfer unit 2 conveys the cell slice 1 on the cell slice roll 6 to a position of the chromatic aberration sensor (not shown in FIG. 4 or FIG. 5), the chromatic aberration sensor detects the presence of the cell slice 1, and then outputs a high level to the controller (not shown in FIG. 4 or FIG. 5); the controller, after receiving this high level, outputs a control signal to a coil of the switching unit, for example, the relay (not shown in FIG. 4 or FIG. 5), the coil after being powered triggers the above mentioned normally open contact to close, then an electrical power of the second power supply is transmitted to the degausser 3 through the relay; the degausser 3 starts to operate after being powered, upon the operation of the transfer unit 2, the cell slice 1 slowly passes through the degausser 3 with a frame-type structure, and the powered degausser 3 generates an alternating magnetic field, so as to perform a uniform degaussing treatment to the forwarding cell slice 1; the degaussed cell slice 1 passes by the residual magnetism meter 4 behind the degausser 3, which residual magnetism meter 4 outputs a residual magnetism value of the cell slice 1 in a digital display manner; In front of the degausser 3, as the cell slice 1 forwarding, the chromatic aberration sensor outputs a low level to the controller after detecting no cell slice 1, and after receiving the low level, the controller cuts off the output to the relay, thus the power supplied by the second power supply to the degausser is cut off, and the degaussing is ended.

As the above embodiment, a time-delay relay can be used as the switching unit, thus when the cell slice 1 leaves a detecting area of the chromatic aberration sensor, the time-delay relay does not immediately cut off the power supplied to the degausser 3, but after a pre-set period of time lapses, for example, after 10 minutes, a contact of the time-delay relay is restored, thereby ensuring that the cell slice 1 can be completely degaussed by the degausser 3, and occurrence of a small part of the cell slice 1 which is not degaussed is avoided.

Likewise, in order to ensure complete degaussing of the cell slice 1, a further sensing unit 5 also can be provided behind the degausser 3 and configured to control the degausser 3 in a delayed manner according to a state of presence or absence of the cell slice 1, thus the power consumption can be reasonably managed and controlled more precisely. The power supplied to the degausser 3 is cut off only when the further sensing unit 5 detects that there is no cell slice 1. Thus, it can ensure that all cell slices 1 can be uniformly degaussed.

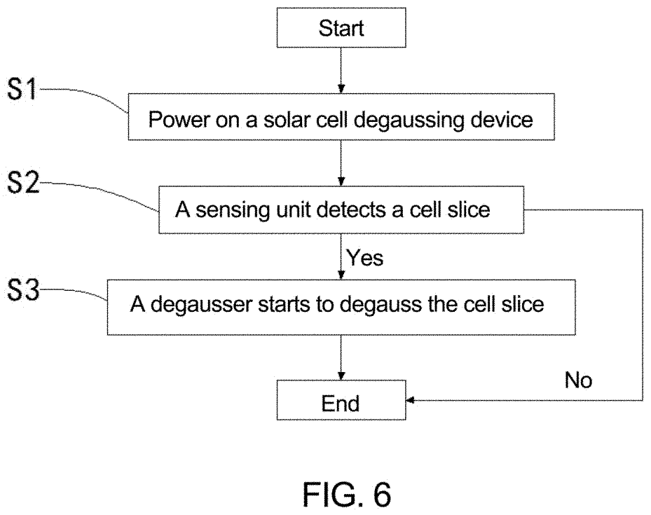

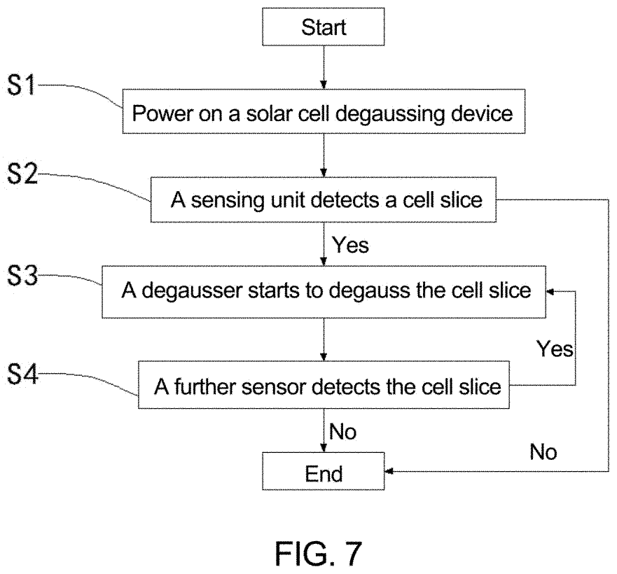

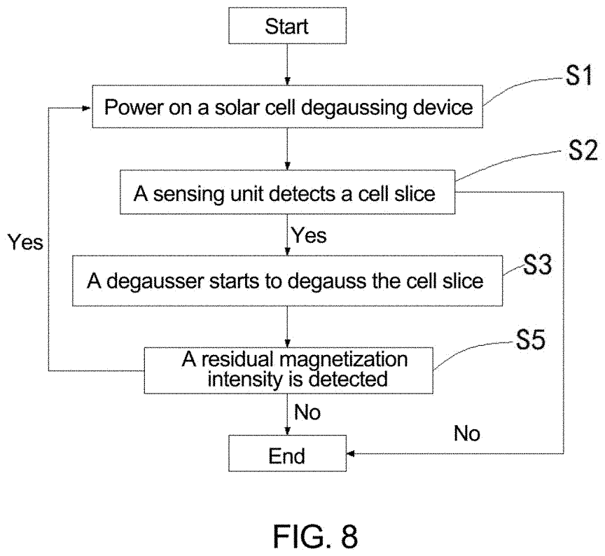

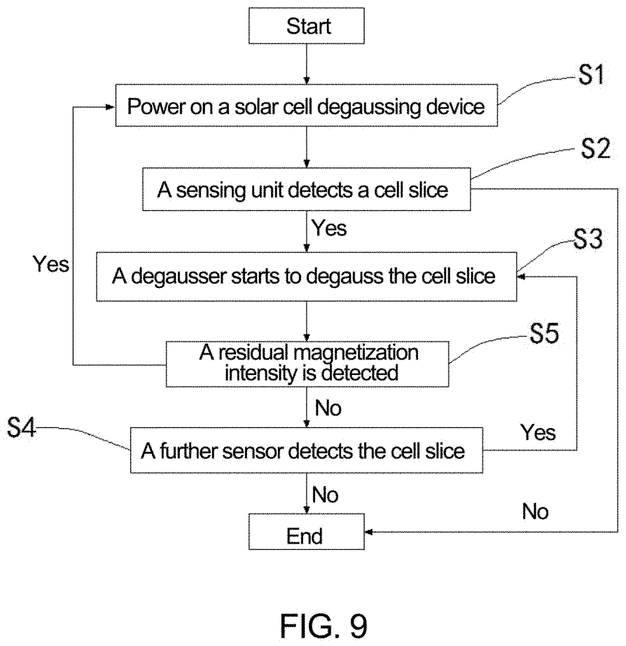

The present disclosure further provides a solar cell degaussing method using the above solar cell degaussing device, and in an embodiment shown in FIG. 6, when the cell slice is degaussed through the solar cell degaussing method, the solar cell degaussing device is powered on (S1), the sensing unit detects the cell slice (S2), and when the sensing units detects the presence of the cell slice, the controller triggers the switching unit to act so as to enable the degausser to operate, thus performing a degaussing treatment to the cell slice (S3), thereafter the degaussing is ended. In Step S2, if the sensing unit detects no cell slice, the degaussing is directly ended. In an embodiment shown in FIG. 7, the further sensor provided behind the degausser according to the cell slice forwarding direction detects the cell slice (S4), and when the further sensor detects no cell slice, the controller controls the switching unit to enable the degausser to end the degaussing. If a cell slice still can be detected in Step S4, the degausser then continues with the degaussing treatment. In an embodiment shown in FIG. 8, after Step S3, the residual magnetism meter provided behind the degausser tracks and detects a residual magnetization intensity of the cell slice after being degaussed (S5), and when the residual magnetization intensity has been detected by the residual magnetism meter, the controller adjusts an operation power of the degausser or controls a driving speed of the transfer unit conveying the cell slice according to the residual magnetization intensity. If no residual magnetization intensity is detected in Step S5, the degaussing is then ended. Similar to the embodiment shown in FIG. 7, in an embodiment shown in FIG. 9, a further sensor provided behind the degausser according to the cell slice forwarding direction detects the cell slice (S4), and when the further sensor detects no cell slice, the controller controls the switching unit to enable the degausser to end the degaussing.

The configurations, features and effects of the present disclosure are described in detail in the above according to the embodiments shown in the figures, while the above-mentioned are merely for embodiments of the present disclosure, it should be stated explicitly that a person skilled in the art can reasonably combine the technical features involved in the above embodiments and preferred embodiments thereof into a plurality of equivalent solutions, without departing from or changing the design idea and technical effects of the present disclosure; therefore, the implementation scope of the present disclosure is not limited to that shown in the figures, but when alterations or modifications made according to the concept of the present disclosure are equivalent embodiments of equal changes, and still do not go beyond the spirit covered by the description and the figures, they all should fall within the scope of protection of the present disclosure.

### INDUSTRIAL APPLICABILITY

To sum up, the present disclosure provides a solar cell degaussing device and a solar cell production system, which can eliminate the magnetism of the magnetized cell slice, decrease the magnetic adsorption phenomena of facilities, and thus improve production efficiency.

1. A solar cell degaussing device, comprising:
a controller, a degausser, a sensing unit and a switching unit,
wherein the controller is connected to the sensing unit and the switching unit respectively;
the switching unit is connected to the degausser; and
after the sensing unit detects presence of a cell slice, the controller triggers the switching unit to act so as to enable the degausser to operate, for performing a degaussing treatment to the cell slice.

2. The solar cell degaussing device of claim 1, further comprising:
a transfer unit configured to carry the cell slice,
the degausser being mounted on the transfer unit.

3. The solar cell degaussing device of claim 2, wherein the transfer unit comprises a plurality of rollers configured to bear the cell slice;
the degausser on the transfer unit is configured for the cell slice to pass through.

4. The solar cell degaussing device of claim 1, wherein the degausser is in a frame-type structure.

5. The solar cell degaussing device of claim 2, further comprising:
a residual magnetism meter;
the residual magnetism meter is mounted behind the degausser according to an operation direction of the transfer unit.

6. The solar cell degaussing device of claim 5, wherein the residual magnetism meter is configured to monitor a residual magnetization intensity of the cell slice after being degaussed.

7. The solar cell degaussing device of claim 6, wherein the residual magnetism meter is connected to the controller;
the controller adjusts an operation power of the degausser or controls a driving speed of the transfer unit according to the residual magnetization intensity.

8. The solar cell degaussing device of claim 5, wherein the sensing unit is mounted in front of the degausser.

9. The solar cell degaussing device of claim 5, wherein a further sensing unit, configured to control the degausser in a delayed manner, is provided behind the degausser.

10. The solar cell degaussing device of claim 1, further comprising:
a first power supply and a second power supply,
wherein the first power supply is connected to the controller and the sensing unit respectively,
the switching unit is connected to the second power supply and the degausser respectively.

11. The solar cell degaussing device of claim 10, wherein the first power supply is a direct current power supply, and the second power supply is an alternating current power supply.

12. The solar cell degaussing device of claim 11, wherein an output voltage of the direct current power supply is 24V, and an output voltage of the alternating current power supply is 220V.

13. The solar cell degaussing device of claim 1, wherein the sensing unit is a chromatic aberration sensor.

14. The solar cell degaussing device of claim 1, wherein the switching unit is a relay.

15. The solar cell degaussing device of claim 14, wherein the relay is a time-delay relay.

16. A solar cell production system configured to produce solar cells, comprising the solar cell degaussing device of claim 1.

17. A solar cell degaussing method, using the solar cell degaussing device of claim 1, wherein the method comprises:
powering on the solar cell degaussing device, after the sensing unit detecting presence of the cell slice, the controller triggering the switching unit to act so as to enable the degausser to operate, for performing a degaussing treatment to the cell slice.

18. The solar cell degaussing method of claim 17, further comprising:
the controller adjusting, when tracking and detecting a residual magnetization intensity of the cell slice degaussed, an operation power of the degausser or controlling a driving speed of the transfer unit for the transmission of the cell slice, according to the residual magnetization intensity.

19. The solar cell degaussing method of claim 17, further comprising:
the controller controlling the switching unit to enable the degausser to end the degaussing, after another sensor, which is provided behind the degausser according to a cell slice forwarding direction, detects no cell slice.

20. The solar cell degaussing method of claim 18, further comprising:
the controller controlling the switching unit to enable the degausser to end the degaussing, after another sensor, which is provided behind the degausser according to a cell slice forwarding direction, detects no cell slice.
